(19) United States
(12) Patent Application Publication
(10) Pub. No.: US 2011/0215433 A1
(43) Pub. Date: Sep. 8, 2011

(54) SOLID STATE IMAGING DEVICE AND SOLID STATE IMAGING DEVICE MANUFACTURING METHOD

(75) Inventor: Koichi Kokubun, Kanagawa (JP)

(73) Assignee: KABUSHIKI KAISHA TOSHIBA, Tokyo (JP)

(21) Appl. No.: 13/038,680

(22) Filed: Mar. 2, 2011

(30) Foreign Application Priority Data
Mar. 5, 2010 (JP) 2010-049519

(51) Int. Cl. H01L 31/0224; H01L 31/18

(52) U.S. Cl. 257/448; 438/73; 257/E31.124

(57) ABSTRACT

According to one embodiment, a solid state imaging device includes a first photoelectric conversion film disposed above a semiconductor substrate, a first common electrode pattern which covers a first portion of the first photoelectric conversion film and has an opening pattern corresponding to a second portion of the first photoelectric conversion film, an insulating film which covers the first common electrode pattern and covers the second portion of the first photoelectric conversion film via the opening pattern, a pixel electrode pattern which covers the insulating film, a second photoelectric conversion film which covers the pixel electrode pattern, a second common electrode pattern which covers the second photoelectric conversion film, and a contact plug which penetrates through the insulating film and the second portion of the first photoelectric conversion film so as to electrically connect the pixel electrode pattern and the semiconductor substrate, wherein the width of the opening pattern is larger than the width of the contact plug.

### CROSS-REFERENCE TO RELATED APPLICATIONS

This application is based upon and claims the benefit of priority from the prior Japanese Patent Application No. 2010-049519, filed on Mar. 5, 2010; the entire contents of which are incorporated herein by reference.

### FIELD

Embodiments described herein relate generally to a solid state imaging device and a solid state imaging device manufacturing method.

### BACKGROUND

As one of new techniques of CMOS image sensors, there is a photoelectric conversion film stacked type CMOS image sensor.

Japanese Patent Application Laid-Open No. 2006-245284 describes a photoelectric conversion film stacked type imaging element in which three photoelectric conversion films for red color (R), green color (G), and blue color (B) are stacked in sequence above a semiconductor substrate. Electric charges generated in each of the photoelectric conversion films flow from a pixel electrode film disposed therebelow via a tungsten plug into a signal charge storage region in the semiconductor substrate. Thereby, according to Japanese Patent Application Laid-Open No. 2006-245284, signals in three colors of red, green, and blue can be detected by one pixel at the same time.

Japanese Patent Application Laid-Open No. 2006-245284 describes that each time a film such as an insulating film is formed, a hole is formed in the film by a resist and dry etching method, and tungsten is buried into the hole to extend the tungsten plug upward. Thereby, as a whole, the number of steps for forming the tungsten plug (contact plug) becomes larger. When the number of steps is large, the manufacturing cost of the photoelectric conversion film stacked type imaging element can be increased.

### BRIEF DESCRIPTION OF THE DRAWINGS

FIG. 1 is a diagram showing the structure of a solid state imaging device according to a first embodiment;

FIGS. 2A to 5B are diagrams showing a manufacturing method of the solid state imaging device according to the first embodiment; and

FIG. 6 is a diagram showing the structure of a solid state imaging device according to a modification example of the first embodiment.

### DETAILED DESCRIPTION

According to one embodiment, a solid state imaging device includes a first photoelectric conversion film disposed above a semiconductor substrate, a first common electrode pattern which covers a first portion of the first photoelectric conversion film and has an opening pattern corresponding to a second portion of the first photoelectric conversion film, an insulating film which covers the first common electrode pattern and covers the second portion of the first photoelectric conversion film via the opening pattern, a pixel electrode pattern which covers the insulating film, a second photoelectric conversion film which covers the pixel electrode pattern, a second common electrode pattern which covers the second photoelectric conversion film, and a contact plug which penetrates through the insulating film and the second portion of the first photoelectric conversion film so as to electrically connect the pixel electrode pattern and the semiconductor substrate, wherein the width of the opening pattern is larger than the width of the contact plug.

A solid state imaging device and a manufacturing method of the same according to an embodiment of the present invention will be explained below in detail with reference to the accompanying drawings. The scope of the present invention is not limited to the embodiment.

### First Embodiment

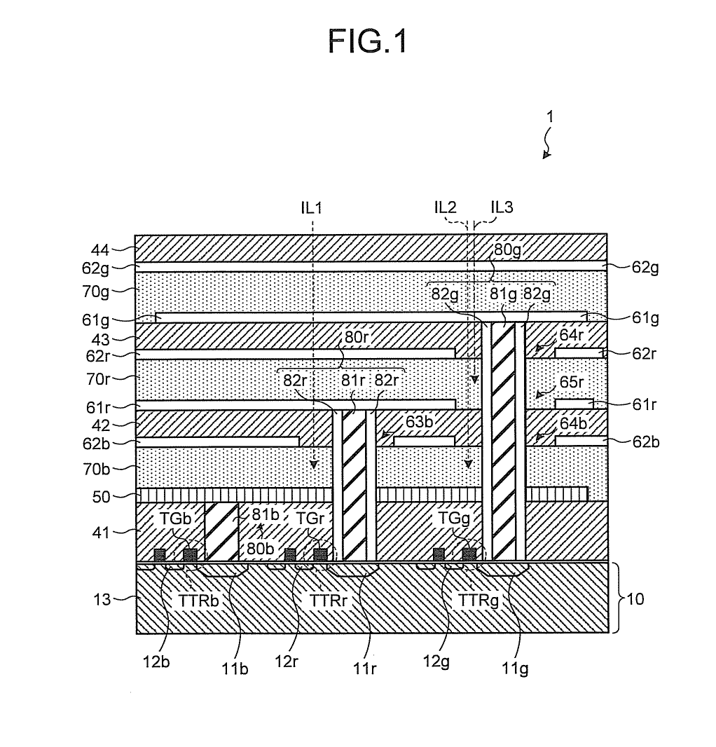

The structure of a solid state imaging device 1 according to a first embodiment will be explained with reference to FIG. 1. FIG. 1 is a diagram showing the cross-sectional structure of the solid state imaging device 1 according to the first embodiment, with respect to one of plural pixels arrayed in an imaging region.

The solid state imaging device 1 has a semiconductor substrate 10, gate electrodes TGb, TGr, and TGg, an insulating film 41, a metal film 50, a photoelectric conversion film (a first photoelectric conversion film) 70b, a common electrode pattern (a first common electrode pattern) 62b, an opening pattern 63b, an opening pattern 64b, an insulating film 42, a pixel electrode pattern 61r, an opening pattern (a second opening pattern) 65r, a photoelectric conversion film (a second photoelectric conversion film) 70r, a common electrode pattern (a second common electrode pattern) 62r, an opening pattern (a third opening pattern) 64r, an insulating film (a second insulating film) 43, a pixel electrode pattern 61g, a photoelectric conversion film 70g, a common electrode pattern 62g, an insulating film 44, a contact plug 80b, a contact plug 80r, and a contact plug (a second contact plug) 80g.

In the semiconductor substrate 10, storage diodes 11b, 11r, and 11g and floating diffusions 12b, 12r, and 12g are arranged in a well region 13. The well region 13 is formed of a semiconductor (e.g., silicon) including impurities of a first conductive type (e.g., a P type) at low density. The p type impurities are, for example, boron. Each of the storage diodes 11b, 11r, and 11g and floating diffusions 12b, 12r, and 12g is formed of a semiconductor (e.g., silicon) including impurities of a second conductive type (e.g., an N type) which is an opposite conductive type of the first conductive type at higher density than the impurities of the first conductive type in the well region 13. The N type impurities are e.g., phosphor or arsenic.

On the semiconductor substrate 10, the gate electrodes TGb, TGr, and TGg and other gate electrodes are disposed. The gate electrode TGb is disposed between the storage diode 11b and the floating diffusion 12b on the semiconductor substrate 10, the gate electrode TGr is disposed between the storage diode 11r and the floating diffusion 12r on the semiconductor substrate 10, and the gate electrode TGg is disposed between the storage diode 11g and the floating diffusion 12g on the semiconductor substrate 10. Thereby, transfer transistors TTRb, TTRr, and TTRg are constituted.

In other words, each of the storage diodes 11b, 11r, and 11g stores electric charges transferred via the corresponding contact plugs 80b, 80r, and 80g. Each of the transfer transistors TTRb, TTRr, and TTRg is turned on when an active level control signal is provided to the corresponding gate electrodes TGb, TGr, and TGg. Thereby, each of the transfer transistors TTRb, TTRr, and TTRg transfers the electric charges in the corresponding storage diodes 11b, 11r, and 11g to the corresponding floating diffusions 12b, 12r, and 12g. Each of the floating diffusions 12b, 12r, and 12g converts the transferred electric charges to voltage. An amplifying transistor, not shown, outputs a signal according to the converted voltage to a signal line.

The insulating film 41 covers the semiconductor substrate 10 and the gate electrodes TGb, TGr, and TGg. Each of the contact plugs 80b, 80r, and 80g penetrates through the insulating film 41.

The metal film 50 is disposed above the semiconductor substrate 10 to cover the insulating film 41. The metal film 50 functions as a pixel electrode which collects electric charges generated in the photoelectric conversion film 70b, and also functions as a light-shielding film which light-shields the surface of the semiconductor substrate 10. The metal film 50 is connected to the storage diode 11b via the contact plug 80b. Each of the contact plugs 80r and 80g penetrates through the metal film 50. The metal film 50 is formed of, for example, a metal or intermetallic compound having aluminum as the main component.

The photoelectric conversion film 70b is disposed on the metal film 50 to cover the metal film 50. Each of the contact plugs 80r and 80g penetrates through the photoelectric conversion film 70b. The photoelectric conversion film 70b absorbs the light in the blue wavelength range of received lights to generate electric charges according to the absorbed light. The photoelectric conversion film 70b is, for example, an organic photoelectric conversion film, and is formed of an organic substance having a characteristic which absorbs the light in the blue wavelength range and transmits the lights in other wavelength ranges therethrough.

The common electrode pattern 62b covers a portion (a first portion) of the photoelectric conversion film 70b. The common electrode pattern 62b applies a bias voltage supplied from the outside to the photoelectric conversion film 70b. Thereby, the electric charges generated in the photoelectric conversion film 70b are easily collected to the metal film 50. The common electrode pattern 62b is isolated from the contact plugs 80r and 80g via the insulating film 42. The common electrode pattern 62b is formed of a transparent conductive substance such as ITO or ZnO. Further, the common electrode pattern 62b may be formed of a semitransparent conductive substance which transmits the light in at least the blue wavelength range therethrough and reflects the light in at least one of the green and red wavelength ranges.

The opening pattern 63b is formed by opening the common electrode pattern 62b. A portion (a second portion) of the photoelectric conversion film 70b located above the storage diode 11r is contacted with the insulating film 42 via the opening pattern 63b. Part of the surface of the photoelectric conversion film 70b is covered by the insulating film 42 via the opening pattern 63b.

The opening pattern 64b is formed by opening the common electrode pattern 62b. A portion (a third portion) of the photoelectric conversion film 70b located above the storage diode 11g is contacted with the insulating film 42 via the opening pattern 64b. Part of the surface of the photoelectric conversion film 70b is covered by the insulating film 42 via the opening pattern 64b.

The insulating film 42 covers the common electrode pattern 62b and the photoelectric conversion film 70b. In other words, the insulating film 42 covers the common electrode pattern 62b, covers the surface of the photoelectric conversion film 70b (the second portion) via the opening pattern 63b, and covers the surface of the photoelectric conversion film 70b (the third portion) via the opening pattern 64b. Each of the contact plugs 80r and 80g penetrates through the insulating film 42. The insulating film 42 is extended so as to bury a region between the common electrode pattern 62b and the contact plug 80r, and is extended so as to bury a region between the common electrode pattern 62b and the contact plug 80g.

The pixel electrode pattern 61r covers a portion (a first portion) of the insulating film 42. The pixel electrode pattern 61r functions as a pixel electrode which collects the electric charges generated in the photoelectric conversion film 70r. The pixel electrode pattern 61r is connected to the storage diode 11r via the contact plug 80r. The pixel electrode pattern 61r is isolated from the contact plug 80g via the photoelectric conversion film 70r. The pixel electrode pattern 61r is formed of a transparent conductive substance such as ITO or ZnO. Further, the pixel electrode pattern 61r may be formed of a semitransparent conductive substance which transmits the light in at least the blue wavelength range therethrough and reflects the light in at least the red and green wavelength range.

The opening pattern 65r is formed by opening the pixel electrode pattern 61r. A portion (a second portion) of the insulating film 42 located above the storage diode 11g is contacted with the photoelectric conversion film 70r via the opening pattern 65r. Part of the surface of the insulating film 42 is covered by the photoelectric conversion film 70r via the opening pattern 65r.

The photoelectric conversion film 70r covers the pixel electrode pattern 61r and the insulating film 42. The contact plug 80g penetrates through the photoelectric conversion film 70r. The photoelectric conversion film 70r is extended so as to bury a region between the pixel electrode pattern 61r and the contact plug 80g. The photoelectric conversion film 70r absorbs the light in the red wavelength range of received lights, and generates electric charges according to the absorbed light. The photoelectric conversion film 70r is, for example, an organic photoelectric conversion film, and is formed of an organic substance having a characteristic which absorbs the light in the red wavelength range and transmits the lights in other wavelength ranges therethrough.

The common electrode pattern 62r covers a portion (a first portion) of the photoelectric conversion film 70r. The common electrode pattern 62r applies a bias voltage supplied from the outside to the photoelectric conversion film 70r. Thereby, the electric charges generated in the photoelectric conversion film 70r are easily collected to the pixel electrode pattern 61r. The common electrode pattern 62r is formed of a transparent conductive substance such as ITO or ZnO. The common electrode pattern 62r is isolated from the contact plug 80g via the insulating film 43. Further, the common electrode pattern 62r may be formed of a semitransparent conductive substance which transmits the lights in at least the blue and red wavelength ranges therethrough and reflects the light in at least the green wavelength range.

The opening pattern 64r is formed by opening the common electrode pattern 62r. A portion (a second portion) of the photoelectric conversion film 70r located above the storage diode 11g is contacted with the insulating film 43 via the opening pattern 64r. Part of the surface of the photoelectric conversion film 70r is covered by the insulating film 43 via the opening pattern 64r.

The insulating film 43 covers the common electrode pattern 62r and the photoelectric conversion film 70r. In other words, the insulating film 43 covers the common electrode pattern 62r, and covers the surface of the photoelectric conversion film 70r (the second portion) via the opening pattern 64r. The contact plug 80g penetrates through the insulating film 43. The insulating film 43 is extended so as to bury a region between the common electrode pattern 62r and the contact plug 80g.

The pixel electrode pattern 61g covers the insulating film 43. The pixel electrode pattern 61g functions as a pixel electrode which collects the electric charges generated in the photoelectric conversion film 70g. The pixel electrode pattern 61g is connected to the storage diode 11g via the contact plug 80g. The pixel electrode pattern 61g is formed of a transparent conductive substance such as ITO or ZnO. Further, the pixel electrode pattern 61g may be formed of a semitransparent conductive substance which transmits the lights in at least the blue and red wavelength ranges therethrough and reflects the light in at least the green wavelength range.

The photoelectric conversion film 70g covers the pixel electrode pattern 61g and the insulating film 43. The photoelectric conversion film 70g absorbs the light in the green wavelength range of received lights, and generates electric charges according to the absorbed light. The photoelectric conversion film 70g is, for example, an organic photoelectric conversion film, and is formed of an organic substance having a characteristic which absorbs the light in the green wavelength range and transmits the lights in other wavelength ranges therethrough.

The common electrode pattern 62g covers the photoelectric conversion film 70g. The common electrode pattern 62g applies a bias voltage supplied from the outside to the photoelectric conversion film 70g. Thereby, the electric charges generated in the photoelectric conversion film 70g are easily collected to the pixel electrode pattern 61g. The common electrode pattern 62g is formed of a transparent conductive substance such as ITO or ZnO. Further, the common electrode pattern 62g may be formed of a semitransparent conductive substance which transmits the lights in at least the green, blue, and red wavelength range therethrough and reflects the light in the predetermined wavelength range.

The insulating film 44 covers the common electrode pattern 62g.

The contact plug 80b penetrates through the insulating film 41 so as to electrically connect the metal film 50 and the storage diode 11b in the semiconductor substrate 10. Thereby, the contact plug 80b transfers the electric charges collected by the metal film 50 to the storage diode 11b. The contact plug 80b includes a conductive portion 81b. The conductive portion 81b is formed of a conductive substance such as tungsten.

The contact plug 80r penetrates through the insulating film 42, the portion (the second portion) of the photoelectric conversion film 70b contacted with the insulating film 42 via the opening pattern 63b, the metal film 50, and the insulating film 41 so as to electrically connect the pixel electrode pattern 61r and the storage diode 11r in the semiconductor substrate 10. Thereby, the contact plug 80b transfers the electric charges collected by the pixel electrode pattern 61r to the storage diode 11r.

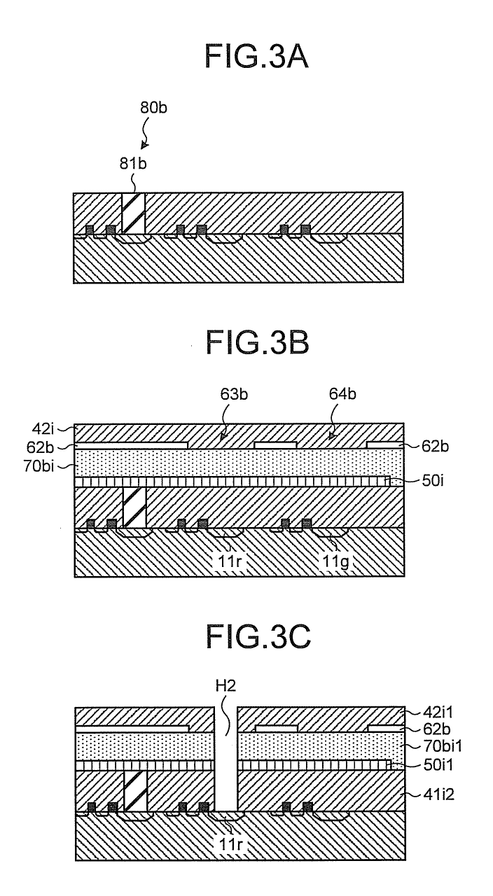

The contact plug 80r includes a conductive portion 81r and an insulating portion 82r. The insulating portion 82r is disposed on the inner side surface of a contact H2 (see FIG. 3C) and surrounds the side surface of the conductive portion 81r. The conductive portion 81r is extended near the center axis of the contact plug 80r from the pixel electrode pattern 61r to the storage diode 11r to electrically connect the both. The conductive portion 81b is formed of a conductive substance such as tungsten. The insulating portion 82r is formed of an insulating substance such as SiO₂.

The contact plug 80g penetrates through the insulating film 43, the portion (the second portion) of the photoelectric conversion film 70r contacted with the insulating film 43 via the opening pattern 64r, the portion (the second portion) of the insulating film 42 contacted with the photoelectric conversion film 70r via the opening pattern 65r, the portion (the third portion) of the photoelectric conversion film 70b contacted with the insulating film 42 via the opening pattern 64b, the metal film 50, and the insulating film 41 so as to electrically connect the pixel electrode pattern 61g and the storage diode 11g in the semiconductor substrate 10. Thereby, the contact plug 80g transfers the electric charges collected by the pixel electrode pattern 61g to the storage diode 11g.

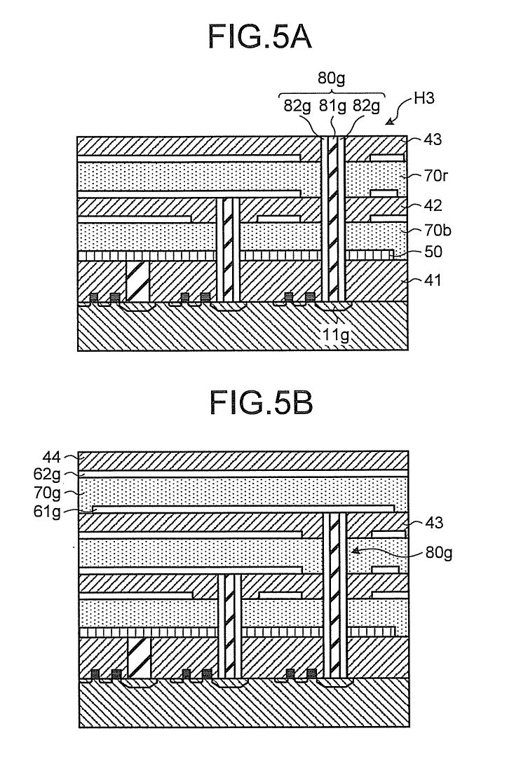

The contact plug 80g includes a conductive portion 81g and an insulating portion 82g. The insulating portion 82g is disposed on the inner side surface of a contact hole H3 (see FIG. 5A), and surrounds the side surface of the conductive portion 81g. The conductive portion 81g is extended near the center axis of the contact plug 80g from the pixel electrode pattern 61g to the storage diode 11g to electrically connect the both. The conductive portion 81g is formed of a conductive substance such as tungsten. The insulating portion 82g is formed of an insulating substance such as SiO₂.

It should be noted that the width (i.e. the area in plan view) of the opening pattern 63b is larger than the width (i.e. the area in plan view) of the contact plug 80r. Specifically, the width of the opening pattern 63b is value according to a process margin larger than the width of the contact plug 80r. The value according to a process margin can be in consideration of misalignment between the region of the storage diode 11r to connect the contact plug 80r and the opening pattern 63b.

In addition, the width of each of the opening patterns 64b, 65r, and 64r is larger than the width of the contact plug 80g. Specifically, the width of each of the opening patterns 64b, 65r, and 64r is value according to a process margin larger than the width of the contact plug 80g. The value according to a process margin can be in consideration of misalignment between the region of the storage diode 11g to connect the contact plug 80g, the opening pattern 64b, the opening pattern 65r, and the opening pattern 64r. Further, since the width of the contact plug 80g can be larger than the width of the contact plug 80r according to the anisotropic limit controllable in dry etching (RIE device), the width of each of the opening patterns 64b, 65r, and 64r can be determined in consideration of that points.

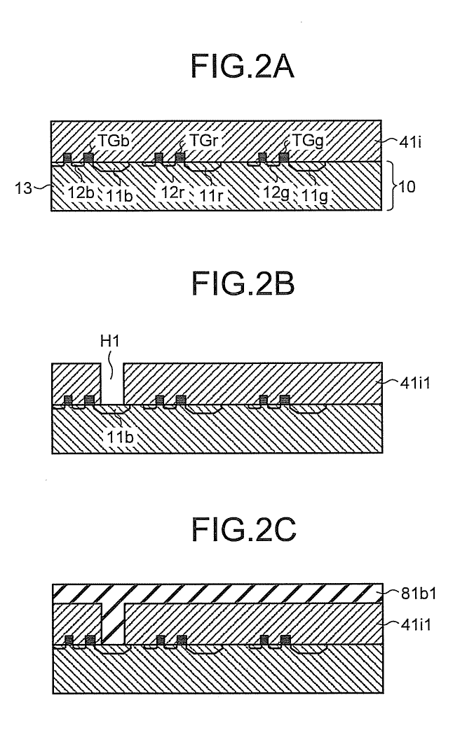

Next, a manufacturing method of the solid state imaging device 1 according to the first embodiment will be explained with reference to FIGS. 2A to 5B.

In the process shown in FIG. 2A, the storage diodes 11b, 11r, and 11g, the floating diffusions 12b, 12r, and 12g, and other semiconductor regions are formed in the well region 13 of the semiconductor substrate 10 by, for example, an ion implantation method. The well region 13 is formed of a semiconductor including impurities of a first conductive type (e.g., a P type) at low density. The storage diodes 11b, 11r, and 11g and the floating diffusions 12b, 12r, and 12g are formed by, for example, implanting impurities of a second conductive type (e.g., an N type) which is an opposite conductive type of the first conductive type into the well region 13 at higher density than the impurities of the first conductive type in the well region 13.

Then, the gate electrodes TGb, TGr, and TGg and other gate electrodes are formed of, for example, polysilicon on the semiconductor substrate 10. Thereafter, an insulating film 41i (e.g., SiO₂) which covers the semiconductor substrate 10, the gate electrodes TGb, TGr, and TGg, and other gate electrodes is formed by, for example, a CVD method.

In the process shown in FIG. 2B, a contact hole H1 which penetrates through the insulating film 41i1 and exposes the surface of the storage diode 11b of the semiconductor substrate 10 by, for example, a lithography method and a dry etching method. The dry etching method is performed, for example, using the RIE device on the condition where the etching anisotropy is enough high to form the contact hole H1 so that the aspect ratio (depth/width) of the contact hole H1 is high.

In the process shown in FIG. 2C, a conductive substance 81b1 (e.g., W) is formed by, for example, a CVD method so as to bury the conductive substance 81b1 into the contact hole H1. At this time, the conductive substance 81b1 is formed so as to cover the top surface of the insulating film 41i1.

In the process shown in FIG. 3A, the conductive substance 81b1 which covers the top surface of the insulating film 41i1 (see FIG. 2C) is removed by, for example, a CMP method to leave the conductive portion 81b in the contact hole H1, thereby forming the contact plug 80b.

In the process shown in FIG. 3B, a metal layer is patterned by, for example, a sputtering method and an RIE method (dry etching method) to form a metal film 50i.

Thereafter, a photoelectric conversion film 70bi is formed on the metal film 50i by a sputtering method.

Then, a common electrode film (not shown) which covers the photoelectric conversion film 70bi is formed by, for example, a sputtering method.

Thereafter, the common electrode film is patterned by, for example, a lithography method and a wet etching method. In other words, the common electrode film is subjected to wet etching with a resist pattern as a mask, to form the common electrode pattern 62b which covers the photoelectric conversion film 70bi, the opening pattern 63b which exposes the portion of the photoelectric conversion film 70bi located above the storage diode 11r, and the opening pattern 64b which exposes the portion of the photoelectric conversion film 70bi located above the storage diode 11g. Further, etching of the common electrode film and the pixel electrode film is performed using, for example, aqua regia as an etchant. This is ditto for the following process.

At this time, the etching time is controlled so that the width of the opening pattern 63b is value according to a process margin larger than the width of the contact plug 80r to be formed. The value according to a process margin can be in consideration of misalignment between the region of the storage diode 11r to connect the contact plug 80r and the opening pattern 63b.

In addition, the etching time is controlled so that the width of the opening pattern 64b is value according to a process margin larger than the width of the contact plug 80g to be formed. The value according to a process margin can be in consideration of misalignment between the region of the storage diode 11g to connect the contact plug 80g, the opening pattern 64b, the opening pattern 65r to be formed, and the opening pattern 64r to be formed. Further, since the width of the contact plug 80g can be larger than the width of the contact plug 80r according to the anisotropic limit controllable in dry etching (the RIE device), the etching time can be controlled so as to obtain the width of the opening pattern 64b in consideration of that point.

Then, an insulating film 42i which covers the common electrode pattern 62b and the photoelectric conversion film 70bi is formed by, for example, a CVD method. At this time, since the width of the opening patterns 63b and 64b becomes larger, the insulating film 42i can be formed so as to cover substantially the entire exposed surface of the photoelectric conversion film 70bi exposed by the opening patterns 63b and 64b.

In the process shown in FIG. 3C, the contact hole (hole) H2 which penetrates through the insulating film 42i1, the portion (a second portion) of the photoelectric conversion film 70bi1 exposed by the opening pattern 63b, a metal film 50i1, and the insulating film 41i2, and exposes the surface of the storage diode 11r of the semiconductor substrate 10 by, for example, a lithography method and a dry etching method. The dry etching method is performed, for example, using the RIE device on the condition where the etching anisotropy is enough high to form the contact hole H2 so that the aspect ratio (depth/width) of the contact hole H2 is high.

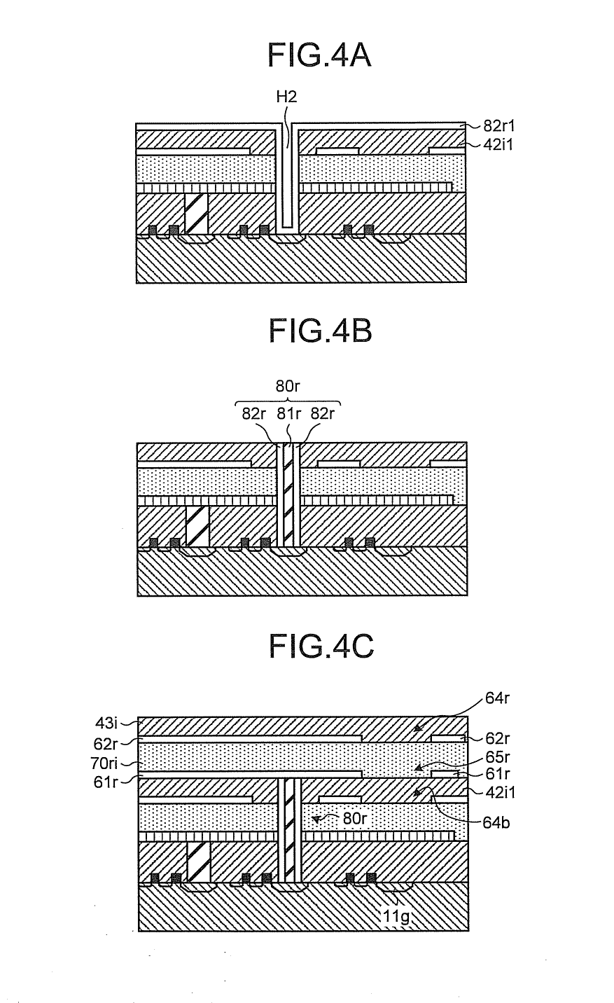

In the process shown in FIG. 4A, an insulating film 82r1 (e.g., SiO₂) which covers the side surface and the bottom surface of the contact hole H2 and the top surface of the insulating film 42i1 is formed by, for example, a CVD method.

In the process shown in FIG. 4B, the portion of the insulating film 82r1 which covers the bottom surface of the contact hole H2 and the portion which covers the top surface of the insulating film 42i1 are selectively removed by, for example, a dry etching method such that the insulating portion 82r on the side surface of the contact hole H2 is remained. The dry etching method is performed, for example, using the RIE device on the condition where the etching anisotropy is enough high.

Next, a conductive substance (not shown; e.g., W) is formed by, for example, a CVD method so as to bury the conductive substance into the contact hole H2. At this time, the conductive substance is formed so as to cover the top surface of the insulating film 42i1. Then, the conductive substance which covers the top surface of the insulating film 42i1 is removed by, for example, a CMP method such that the conductive portion 81r in the contact hole H2 is remained. Thereby, the contact plug 80r having the conductive portion 81r and the insulating portion 82r is formed.

In the process shown in FIG. 4C, the pixel electrode film (not shown) which covers the contact plug 80r and the insulating film 42i1 is formed by, for example, a sputtering method.

Thereafter, the pixel electrode film is patterned by, for example, a lithography method and a wet etching method. In other words, the pixel electrode film is subjected to wet etching with a resist pattern as a mask, to form the pixel electrode patterns 61r which covers the insulating film 42i1, and the opening pattern 65r which exposes the portion of the insulating film 42i1 located above the storage diode 11g.

At this time, the etching time is controlled so that the width of the opening pattern 65r is value according to a process margin larger than the width of the contact plug 80g to be formed. The value according to a process margin can be in consideration of misalignment between the region of the storage diode 11g to connect the contact plug 80g, the opening pattern 64b, the opening pattern 65r, and the opening pattern 64r to be formed. In addition, since the width of the contact plug 80g can be larger than the width of the contact plug 80r according to the anisotropic limit controllable in dry etching (RIE device), the etching time can be controlled so as to obtain the width of the opening pattern 65r in consideration of that point.

Thereafter, a photoelectric conversion film 70ri which covers the pixel electrode pattern 61r and the insulating film 42i1 is formed by, for example, a sputtering method. The photoelectric conversion film 70ri is formed of, for example, an organic substance having a characteristic which absorbs the light in the red wavelength range and transmits the lights in other wavelength ranges therethrough. At this time, since the width of the opening pattern 65r becomes larger, the photoelectric conversion film 70ri can be formed so as to cover substantially the entire exposed surface of the insulating film 42i1 exposed by the opening pattern 65r.

Then, the common electrode film (not shown) which covers the photoelectric conversion film 70ri is formed by, for example, a sputtering method.

Thereafter, the common electrode film is patterned by a lithography method and a wet etching method. In other words, the common electrode film is subjected to wet etching with a resist pattern as a mask, to form the common electrode pattern 62r which covers the photoelectric conversion film 70ri, and the opening pattern 64r which exposes the portion of the photoelectric conversion film 70ri located above the storage diode 11g.

At this time, the etching time is controlled so that the width of the opening pattern 64r is value according to a process margin larger than the width of the contact plug 80g to be formed. The value according to a process margin can be in consideration of misalignment between the region of the storage diode 11g to connect the contact plug 80g, the opening pattern 64b, the opening pattern 65r, and the opening pattern 64r. In addition, since the width of the contact plug 80g can be larger than the width of the contact plug 80r according to the anisotropic limit controllable in dry etching (RIE device), the etching time can be controlled so as to obtain the width of the opening pattern 64r in consideration of that point.

Then, an insulating film 43i which covers the common electrode pattern 62r and the photoelectric conversion film 70ri is formed by a CVD method. At this time, since the width of the opening pattern 64r becomes larger, the insulating film 43i can be formed so as to cover substantially the entire exposed surface of the photoelectric conversion film 70ri exposed by the opening pattern 64r.

In the process shown in FIG. 5A, the contact hole (the second hole) H3 which penetrates through the insulating film 43, the portion (the second portion) of the photoelectric conversion film 70r exposed by the opening pattern 64r (see FIG. 4C), the portion (the second portion) of the insulating film 42 exposed by the opening pattern 65r, the portion (the third portion) of the photoelectric conversion film 70b exposed by the opening pattern 64b, the metal film 50, and the insulating film 41, and exposes the surface of the storage diode 11g of the semiconductor substrate 10 is formed by, for example, a lithography method and a dry etching method. The dry etching method is performed, for example, using the RIE device on the condition where the etching anisotropy is enough high to form the contact hole H3 so that the aspect ratio (depth/width) of the contact hole H3 is high.

Then, an insulating film (not shown) which covers the side surface and the bottom surface of the contact hole H3 and the top surface of the insulating film 43 is formed by, for example, a CVD method. The insulating film is formed of, for example, SiO₂.

Thereafter, the portion of the insulating film which covers the bottom surface of the contact hole H3 and the portion which covers the top surface of the insulating film 43i are selectively removed by a dry etching method such that the insulating portion 82g on the side surface of the contact hole H3 is remained. The dry etching method is performed, for example, using the RIE device on the condition where the etching anisotropy is enough high.

Next, a conductive substance (not shown) is formed by a CVD method so as to bury the conductive substance into the contact hole H3. At this time, the conductive substance is formed so as to cover the top surface of the insulating film 43i. The conductive substance is formed of, for example, tungsten. Then, the conductive substance which covers the top surface of the insulating film 43i is removed by, for example, a CMP method such that the conductive portion 81g in the contact hole H3 is remained. Thereby, the contact plug 80g having the conductive portion 81g and the insulating portion 82g is formed.

In the process shown in FIG. 5B, the pixel electrode film (not shown) which covers the contact plug 80g and the insulating film 43 is formed by, for example, a sputtering method.

Thereafter, the pixel electrode film is patterned by, for example, a lithography method and a wet etching method. In other words, the pixel electrode film is subjected to wet etching with a resist pattern as a mask, to form the pixel electrode pattern 61g which covers the insulating film 43.

Then, the photoelectric conversion film 70g which covers the pixel electrode pattern 61g is formed by a sputtering method.

Next, the common electrode film (not shown) which covers the photoelectric conversion film 70ri is formed by, for example, a sputtering method.

Thereafter, the common electrode film is patterned by a lithography method and a wet etching method. In other words, the common electrode film is subjected to wet etching with a resist pattern as a mask, to form the common electrode pattern 62g which covers the photoelectric conversion film 70g.

Then, the insulating film 44 which covers the common electrode pattern 62g is formed by a CVD method.

As described above, in the first embodiment, plural stacked films are subjected to dry etching together (continuously in the same chamber) to form the contact hole, so that it is easy to allow the aspect ratio (depth/width) of the contact hole to be higher. With this process, it is easy to allow the proportion of the area of the contact plug formed by burying the conductive substance into the contact hole, of the total area of the pixel to be smaller. As a result of this, the reduction of the light received area of the photoelectric conversion film lower than the topmost film can be easily suppressed.

It should be noted that, the order of stacking the photoelectric conversion films 70b, 70r, and 70g which absorb the lights in the blue, red, and green wavelength ranges to perform photoelectric conversion is not limited to the order shown in FIG. 1, and other orders may be used.

In that case, the common electrode pattern and the pixel electrode pattern may be formed of a semitransparent substance which transmits any of the lights in the wavelength ranges to be photoelectrically converted by the respective photoelectric conversion films disposed therebelow, and reflects the light in the wavelength range to be photoelectrically converted by each of the photoelectric conversion films disposed thereabove.

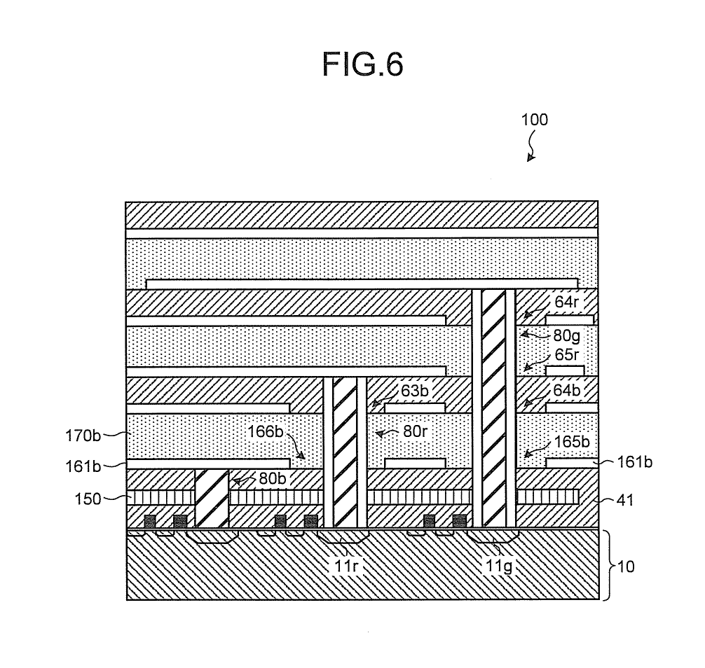

In addition, as shown in FIG. 6, in a solid state imaging device 100, a metal film 150 for masking may be disposed between a pixel electrode pattern 161b and the semiconductor substrate 10. In this case, an opening pattern 166b is disposed adjacent to the pixel electrode pattern 161b. The opening pattern 166b exposes the portion of the insulating film 41 located above the storage diode 11r. The surface of the insulating film 41 exposed by the opening pattern 166b is covered by a photoelectric conversion film 170b. The photoelectric conversion film 170b is extended so as to bury a region between the pixel electrode pattern 161b and the contact plug 80r. In addition, an opening pattern 165b is disposed adjacent to the pixel electrode pattern 161b. The opening pattern 165b exposes the portion of the photoelectric conversion film 170b located above the storage diode 11g. The surface of the photoelectric conversion film 170b exposed by the opening pattern 165b is covered by the photoelectric conversion film 170b. The photoelectric conversion film 170b is extended so as to bury a region between the pixel electrode pattern 161b and the contact plug 80g.

In the manufacturing method of the solid state imaging device 100 shown in FIG. 6, the metal film 150 is formed after the lower half of the insulating film 41 is formed. Thereafter, the upper half of the insulating film 41 is formed so as to cover the metal film 150. Then, after the contact plug 80b is formed, the pixel electrode film which covers the contact plug 80b and the insulating film 41 is formed. Further, the pixel electrode film is subjected to wet etching with a resist pattern as a mask, to form the pixel electrode pattern 161b which covers the insulating film 41, the opening pattern 166b which exposes the portion of the insulating film 41 located above the storage diode 11r, and the opening pattern 165b which exposes the portion of the insulating film 41 located above the storage diode 11g. As the etchant, for example, aqua regia is used.

At this time, the etching time is controlled so that the width of the opening pattern 166b is value according to a process margin larger than the width of the contact plug 80r to be formed. The value according to a process margin can be in consideration of misalignment between the region of the storage diode 11r to connect the contact plug 80r, the opening pattern 166b, and the opening pattern 63b to be formed.

In addition, the etching time is controlled so that the width of the opening pattern 165b is value according to a process margin larger than the width of the contact plug 80g to be formed. The value according to a process margin can be in consideration of misalignment between the region of the storage diode 11g to connect the contact plug 80g, the opening pattern 165b, the opening pattern 64b, the opening pattern 65r, and the opening pattern 64r to be formed.

Therefore, in the manufacturing method of the solid state imaging device 100, in later dry etching process, in the state where the film which is difficult to be processed by a dry etching method is not included in the region to be etched, plural stacked films are subjected to dry etching together (continuously in the same chamber) to form the contact hole at high aspect ratio (depth/width) so that the conductive substance can be buried into the contact hole.

With this process also, it is easy to allow the proportion of the area of the contact plug formed by burying the conductive substance into the contact hole, of the total area of the pixel to be smaller. As a result of this, the reduction of the light received area of the photoelectric conversion film lower than the topmost film can be easily suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid state imaging device comprising:
a first photoelectric conversion film disposed above a semiconductor substrate;
a first common electrode pattern which covers a first portion of the first photoelectric conversion film and has an opening pattern corresponding to a second portion of the first photoelectric conversion film;
an insulating film which covers the first common electrode pattern and covers the second portion of the first photoelectric conversion film via the opening pattern;
a pixel electrode pattern which covers the insulating film;
a second photoelectric conversion film which covers the pixel electrode pattern;
a second common electrode pattern which covers the second photoelectric conversion film; and
a contact plug which penetrates through the insulating film and the second portion of the first photoelectric conversion film so as to electrically connect the pixel electrode pattern and the semiconductor substrate,
wherein the width of the opening pattern is larger than the width of the contact plug.

2. The solid state imaging device according to claim 1,
wherein the insulating film is extended so as to bury a region between the first common electrode pattern and the contact plug.

3. The solid state imaging device according to claim 1,
wherein each of the first common electrode pattern, the pixel electrode pattern, and the second common electrode pattern is formed of a transparent conductive substance or a semitransparent conductive substance.

4. The solid state imaging device according to claim 1,
wherein the semiconductor substrate has a semiconductor region,
the second portion of the first photoelectric conversion film is located above the semiconductor region, and
the contact plug electrically connects the pixel electrode pattern and the semiconductor region.

5. The solid state imaging device according to claim 4,
wherein the width of the opening pattern is value according to misalignment larger than the width of the contact plug, the misalignment being misalignment between a region of the semiconductor region to connect the contact plug and the opening pattern.

6. The solid state imaging device according to claim 1, further comprising a metal film which is covered by the first photoelectric conversion film and functions as a pixel electrode of the first photoelectric conversion film,
wherein the contact plug penetrates through the insulating film, the second portion of the first photoelectric conversion film, and the metal film.

7. The solid state imaging device according to claim 1,
wherein the first common electrode pattern further has a second opening pattern corresponding to a third portion of the first photoelectric conversion film,
the insulating film covers the third portion of the first photoelectric conversion film via the second opening pattern, and
the pixel electrode pattern covers a first portion of the insulating film and has a third opening pattern corresponding to a second portion of the insulating film, and
the second photoelectric conversion film covers the second portion of the insulating film via the third opening pattern.

8. The solid state imaging device according to claim 7,
wherein the second common electrode pattern covers a first portion of the second photoelectric conversion film and has a fourth opening pattern corresponding to a second portion of the second photoelectric conversion film,
the solid state imaging device further comprising:
a second insulating film which covers the second common electrode pattern and covers the second portion of the second photoelectric conversion film via the fourth opening pattern;
a second pixel electrode pattern which covers the second insulating film;
a third photoelectric conversion film which covers the second pixel electrode pattern;
a third common electrode pattern which covers the third photoelectric conversion film; and
a second contact plug which penetrates through the second insulating film, the second portion of the second photoelectric conversion film, the second portion of the insulating film, and the third portion of the first photoelectric conversion film so as to electrically connect the second pixel electrode pattern and the semiconductor substrate,
wherein the width of the second contact plug is larger than the width of the contact plug.

9. The solid state imaging device according to claim 8,
wherein the insulating film is extended so as to bury a region between the first common electrode pattern and the contact plug, and to bury a region between the first common electrode pattern and the second contact plug,
the second insulating film is extended so as to bury a region between the second common electrode pattern and the second contact plug.

10. The solid state imaging device according to claim 8,
wherein the width of the second contact plug is larger than the width of the contact plug according to the anisotropic limit controllable in a dry etching method.

11. The solid state imaging device according to claim 8,
wherein each of the first common electrode pattern, the pixel electrode pattern, the second common electrode pattern, the second pixel electrode pattern, and the third common electrode pattern is formed of a transparent conductive substance or a semitransparent conductive substance.

12. The solid state imaging device according to claim 8,
wherein the semiconductor substrate has a second semiconductor region,
each of the second portion of the second photoelectric conversion film, the second portion of the insulating film, and the third portion of the first photoelectric conversion film is located above the second semiconductor region, and
the second contact plug electrically connects the second pixel electrode pattern and the second semiconductor region.

13. The solid state imaging device according to claim 12,
wherein each of the width of the second opening pattern, the width of the third opening pattern, and the width of the fourth opening pattern is value according to misalignment larger than the width of the second contact plug, the misalignment being misalignment between a region of the second semiconductor region to connect the second contact plug, the second opening pattern, the third opening pattern, and the fourth opening pattern.

14. The solid state imaging device according to claim 8, further comprising a metal film which is covered by the first photoelectric conversion film and functions as a pixel electrode of the first photoelectric conversion film,
wherein the second contact plug penetrates through the second insulating film, the second portion of the second photoelectric conversion film, the second portion of the insulating film, the third portion of the first photoelectric conversion film, and the metal film.

15. The solid state imaging device according to claim 1, further comprising:
a metal film disposed between the semiconductor substrate and the first photoelectric conversion film;
a third insulating film disposed between the first photoelectric conversion film and the metal film; and
a third pixel electrode pattern which covers a first portion of the third insulating film and has a fifth opening pattern corresponding to a second portion of the third insulating film,
wherein the contact plug penetrates through the insulating film, the second portion of the first photoelectric conversion film, the second portion of the third insulating film, and the metal film.

16. The solid state imaging device according to claim 8, further comprising:
a metal film disposed between the semiconductor substrate and the first photoelectric conversion film;
a third insulating film disposed between the first photoelectric conversion film and the metal film; and
a third pixel electrode pattern which covers a first portion of the third insulating film and has a sixth opening pattern corresponding to a third portion of the third insulating film,
wherein the second contact plug penetrates through the second insulating film, the second portion of the second photoelectric conversion film, the second portion of the insulating film, the third portion of the first photoelectric conversion film, the second portion of the third insulating film, and the metal film.

17. A solid state imaging device manufacturing method comprising:
forming a photoelectric conversion film above a semiconductor substrate;
forming a common electrode film which covers the photoelectric conversion film;
processing the common electrode film such that a common electrode pattern which covers a first portion of the photoelectric conversion film and an opening pattern which exposes a second portion of the photoelectric conversion film are formed;
forming an insulating film which covers the common electrode pattern and the second portion exposed by the opening pattern;
forming a hole which penetrates through the insulating film and the second portion of the photoelectric conversion film and exposes the surface of the semiconductor substrate; and
burying a conductive substance into the hole to form a contact plug,
wherein the width of the opening pattern is larger than the width of the contact plug.

18. The solid state imaging device manufacturing method according to claim 17,
wherein the processing of the common electrode film is performed by a wet etching method, and
the forming of the hole is performed by a dry etching method.

19. The solid state imaging device manufacturing method according to claim 17,
wherein the processing of the common electrode film is performed such that a second opening pattern which exposes a third portion of the photoelectric conversion film are further formed,
the forming of the insulating film forms the insulating film which covers the common electrode pattern, the second portion of the photoelectric conversion film, and the third portion of the photoelectric conversion film.

20. The solid state imaging device manufacturing method according to claim 19, further comprising:
forming a pixel electrode film which covers the contact plug and the insulating film after forming the contact plug;
processing the pixel electrode film such that a pixel electrode pattern which covers the contact plug and a first portion of the insulating film and a third opening pattern which exposes a second portion of the insulating film are formed;
forming a second photoelectric conversion film which covers the pixel electrode pattern and the second portion of the insulating film exposed by the third opening pattern;
forming a second common electrode film which covers the second photoelectric conversion film;
processing the second pixel electrode film such that a second common electrode pattern which covers a first portion of the second photoelectric conversion film and a fourth opening pattern which exposes a second portion of the second photoelectric conversion film are formed;
forming a second insulating film which covers the second common electrode pattern and the second portion of the second photoelectric conversion film exposed by the fourth opening pattern;
forming a second hole which penetrates through the second insulating film, the second portion of the second photoelectric conversion film, the second portion of the insulating film, and a third portion of the photoelectric conversion film and exposes the surface of the semiconductor substrate; and
burying a conductive substance into the second hole to form a second contact plug,
wherein the width of the second contact plug is larger than the width of the contact plug.
